(19) United States
(12) Patent Application Publication
(10) Pub. No.: US 2026/0113955 A1
(43) Pub. Date: Apr. 23, 2026

(54) SEMICONDUCTOR MEMORY DEVICE

(71) Applicant: Samsung Electronics Co., Ltd., Suwon-si (KR)

(72) Inventors: Sumin Yu, Suwon-si (KR); Hwayeong Lee, Suwon-si (KR)

(21) Appl. No.: 19/210,022

(22) Filed: May 16, 2025

(30) Foreign Application Priority Data
Oct. 21, 2024 (KR) 10-2024-0144117

(51) Int. Cl. H10B 63/00

(52) U.S. Cl. CPC H10B 63/24

(57) ABSTRACT

Disclosed is a semiconductor memory device including: a substrate; a plurality of word lines extending along a first direction on the substrate; a plurality of bit lines on the word lines and extending along a second direction intersecting the first direction; and a memory cell between the word lines and the bit lines, a word line of the plurality of word lines including a first portion, a second portion, and a third portion, and in a plan view, a width of the first portion is less than a width of the second portion in the second direction, and a width of the second portion is less than a width of the third portion in the second direction.

### CROSS-REFERENCE TO RELATED APPLICATION

This application claims priority to and the benefit of Korean Patent Application No. 10-2024-0144117 filed in the Korean Intellectual Property Office on Oct. 21, 2024, the entire contents of which are incorporated herein by reference.

### TECHNICAL FIELD

The present invention relates to a semiconductor memory device.

### BACKGROUND OF THE INVENTION

Semiconductor memory devices are widely used to store information in various electronic devices, such as computers, wireless communication devices, cameras, and digital displays. Information may be stored by programming different states of the semiconductor memory device. For example, the semiconductor memory device may have two states, denoted as logic “1” or logic “0”. To access the stored information, a component of the electronic device may read or sense the stored state within the semiconductor memory device. To store information, a component of the electronic device may also write or program the state within the semiconductor memory device.

### SUMMARY OF THE INVENTION

The present disclosure provides a semiconductor memory device with improved reliability.

Embodiments of the present disclosure provide a semiconductor memory device including: a substrate; a plurality of word lines extending along a first direction on the substrate; a plurality of bit lines on the word lines and extending along a second direction intersecting the first direction; and a memory cell between the word lines and the bit lines, a word line of the plurality of word lines including a first portion, a second portion, and a third portion, and in a plan view, a width of the first portion is less than a width of the second portion in the second direction, and a width of the second portion is less than a width of the third portion in the second direction.

Another embodiment of the present disclosure provides a semiconductor memory device including: a substrate; a plurality of word lines extending along a first direction on the substrate; a plurality of bit lines on the word lines and extending along a second direction intersecting the first direction ; and a memory cell between the word lines and the bit lines and including a first electrode in contact with a word line of the plurality of word lines, a second electrode in contact with a bit line of the plurality of bit lines, and a first OTS film between the first electrode and the second electrode. The word line includes a first portion, a second portion, and a third portion, and an area of contact between the first portion of the word line and the memory cell is less than an area of contact between the second portion of the word line and the memory cell.

Still another embodiment of the present disclosure provides a semiconductor memory device including: a substrate; a plurality of word lines extending along a first direction on the substrate and comprising a first word line and a second word line adjacent to the first word line in a second direction intersecting the first direction; a plurality of bit lines on the word lines and extending along the second direction ; a memory cell between the word lines and the bit lines; and row decoders on opposite ends of the plurality of word lines in the first direction, a word line of the plurality of word lines including a first portion, a second portion, and a third portion consecutively in the first direction, the first portion, second portion, and third portion having different widths in the second direction, the second word line comprises a third portion, a second portion, and a first portion consecutively in the first direction, and the first portion of each word line is directly connected to one of the row decoders.

According to the embodiments, a semiconductor memory device with improved reliability is provided.

### BRIEF DESCRIPTION OF THE DRAWINGS

FIG. 1 is a diagram illustrating an operation method of a memory device according to embodiments.

FIG. 2 is a simplified schematic diagram illustrating a planar shape of a row decoder and a word line in the embodiments of FIG. 1.

FIG. 3 is a diagram illustrating an example configuration of a memory cell in FIG. 2.

FIG. 4 is a perspective view of a portion indicated by A in FIG. 3.

FIG. 5 is a cross-sectional view taken along line A-A′ in FIG. 4.

FIG. 6 is a perspective view of a portion indicated by B in FIG. 3.

FIG. 7 is a cross-sectional view taken along line A-A′ of FIG. 6.

FIG. 8 is a perspective view of a portion indicated by C of FIG. 3.

FIG. 9 is a cross-sectional view taken along line A-A′ of FIG. 8.

FIG. 10 is a simplified cross-sectional view of a first word line and a first memory cell.

FIG. 11 is a diagram illustrating the same area as FIG. 10 for other embodiments.

FIG. 12 is a diagram illustrating the same area as FIG. 11 for other embodiments.

FIG. 13 is a diagram illustrating the same area as FIG. 12 for other embodiments.

FIG. 14 is a diagram illustrating a conductive path of a first OTS film during each operation in a memory device in which a width of a first electrode and a width of a word line are the same.

FIG. 15 is a diagram illustrating a conductive path of a first OTS film during each operation in a memory device in which a width of a word line is narrower than a width of a first electrode.

FIGS. 16 to 28 are diagrams illustrating a method of manufacturing a memory device according to embodiments.

FIGS. 29 to 33 illustrate a method for manufacturing a memory device according to embodiments.

### DETAILED DESCRIPTION OF THE EMBODIMENTS

In the following detailed description, only certain embodiments of the present invention have been illustrated and described, simply by way of illustration. The present invention may be implemented including many variations and is not limited to the following embodiments.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the present invention is not limited thereto. In the drawings, the thickness of layers, films, panels, regions, etc., are exaggerated for clarity. In the drawings, for understanding and ease of description, the thickness of some layers and areas is exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, it will be understood that when an element such as a layer, film, region, or substrate is referred to as being “on” another element, it may be directly on the other element or intervening elements may also be present.

In addition, unless explicitly described to the contrary, the word “comprise”, and variations such as “comprises” or “comprising”, will be understood to imply the inclusion of stated elements but not the exclusion of any other elements. The term “and/or” includes any and all combinations of one or more of the associated listed items. Components or layers described with reference to “overlap” in a particular direction may be at least partially obstructed by one another when viewed along a line extending in the particular direction or in a plane perpendicular to the particular direction.

Further, in the entire specification, when it is referred to as “in a plan view”, it means when a target part is viewed from above, and when it is referred to as “in a cross-sectional view”, it means when the cross-section obtained by cutting a target part vertically is viewed from the side.

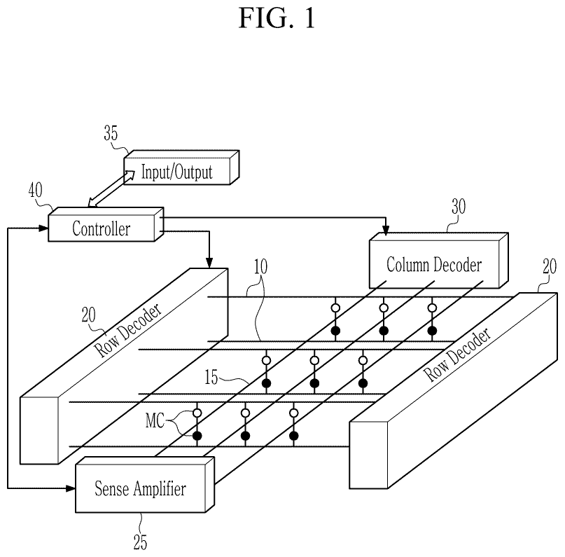

FIG. 1 is a diagram illustrating an operation method of a memory device according to embodiments.

Referring to FIG. 1, a semiconductor memory device according to embodiments may include one or more memory cells MCs. Each memory cell MC may be programmable to store two states, denoted as logic “0” and logic “1”. In some embodiments, the memory cell MC may store more than two logic states.

The memory cell MC may include an information storage element representing a logic state. The information storage element may include a chalcogenide material. The chalcogenide material may have a variable threshold voltage or variable resistance. The chalcogenide material may function as an information storage element. The chalcogenide material may include a compound in which at least one of chalcogen elements S, Te, and/or Se is combined with at least one of Ge, Sb, Bi, Al, Tl, Sn, Zn, As, Si, In, Ti, Ga, and/or P.

In embodiments, the threshold voltage of the cell may be changed depending on the polarity used to program the cell. For example, a magnetic-selected memory cell programmed with one polarity may have one threshold voltage depending on specific resistance. Different polarities may be programmed which may produce different threshold voltages depending on different resistance characteristics of the magnetic-selected memory cell. When the magnetic-selected memory cell is programmed, ions within the chalcogenide material may move. The ions may move toward a specific electrode depending on a predetermined polarity of the cell. For example, in a magnetic-selected memory cell, the ions may move toward the negative electrode. The magnetic-selected memory cell may then be read by applying a voltage to the magnetic-selected memory cell to sense which electrode the ions moved toward.

The threshold voltage of the cell may be adjusted by utilizing the crystalline structure or atomic arrangement of the chalcogenide material. For example, materials having crystalline or amorphous atomic arrangements may have different resistances. The crystalline state may have low resistance. The amorphous state may have high resistance. Therefore, the voltage applied to the memory cell MC may generate different currents depending on whether the chalcogenide material is in the crystalline state or the amorphous state. Further, the magnitude of the generated current may determine the logic state stored by the memory cell MC.

A memory array of the semiconductor memory device according to embodiments may be configured in two dimensions (2D) or in three dimensions (3D). A three-dimensional (3D) memory array may be a structure in which memory cells MC are vertically stacked. A three-dimensional memory array may increase the number of memory cells MCs that may be formed on one substrate compared to a two-dimensional memory array. In FIG. 1, the memory cell MC may be a three-dimensional memory array including two layers. However, embodiments of the present invention are not limited thereto. The memory cells MCs may be aligned across each layer. The memory cells MCs may form a memory cell stack.

The memory cell MC may be connected to a first conductive line 10 and a second conductive line 15. The first conductive line 10 may be a word line, and the second conductive line 15 may be a bit line, but embodiments of the present invention are not limited thereto. The first conductive line 10 and the second conductive line 15 may extend substantially perpendicularly to each other.

One memory cell MC may be disposed at the intersection of the first conductive line 10 and the second conductive line 15. The intersection may also be referred to as an address of the memory cell MC. A target memory cell MC may be positioned at the intersection of a word line and a bit line to which voltage is applied. That is, the first conductive line 10 and the second conductive line 15 may function to read or write the memory cell MC at their intersection.

In embodiments, the reading and writing may include applying a voltage or current to each conductive line. Reading and writing may be performed in the memory cell MC by activating or selecting the first conductive line 10 and the second conductive line 15. The first conductive line 10 and the second conductive line 15 may include a conductive material. For example, the first conductive line 10 and the second conductive line 15 may include a metal material such as copper (Cu), aluminum (Al), gold (Au), tungsten (W), and titanium (Ti), a metal alloy, carbon, a semiconductor material doped with a conductive property, and/or other conductive materials. When the memory cell MC is selected, for example, the movement of selenium (Se) ions may be influenced to set the logic state of the cell.

For example, the memory cell MC may be programmed by applying an electrical pulse to a chalcogenide material including selenium (Se). The pulse may be provided, for example, through the first conductive line 10 or the second conductive line 15. When the pulse is provided, the selenium (Se) ions may move within the information storage element depending on the polarity of the memory cell MC. Therefore, the concentration of selenium (Se) on the surface of the information storage element may be influenced by the polarity of the voltage between the first conductive line 10 and the second conductive line 15.

A voltage may be applied to the memory cell MC to read the cell. The threshold voltage at the time at which the current generated by the application of the voltage begins to flow may represent a state of logic “1” or logic “0”. The concentration difference of selenium (Se) ions at the end of the information storage element may affect the threshold voltage. The concentration difference of selenium (Se) ions at the end of the information storage element may cause a larger difference in cell response between logic states.

Access to the memory cell MC may be controlled via a row decoder 20 and a column decoder 30. For example, the row decoder 20 may receive a row address from the controller 40. Additionally, the row decoder 20 may activate an appropriate first conductive line 10 based on the row address received from the controller 40. Similarly, the column decoder 30 may receive a column address from the controller 40. In addition, the column decoder 30 may activate the second conductive line 15 based on the column address received from the controller 40. By activating the first conductive line 10 and the second conductive line 15, the memory cell MC may be accessed.

As illustrated in FIG. 1, the row decoder 20 may be positioned on opposite sides of the first conductive line 10. As will be described later, the semiconductor memory device according to present embodiments is characterized by forming the width of the word line, i.e., the first conductive line 10 on a plane differently for each region. In this case, the row decoder 20 may be positioned on opposite sides of the first conductive line 10 to efficiently utilize the plane space. The specific plane arrangement of the first conductive line 10 and the connection relationship with the row decoder 20 will be described separately later.

When accessing the memory cell MC, the memory cell MC may be read or sensed by a sense amplifier 25. For example, the sense amplifier 25 may determine the logical state stored in the memory cell MC based on a signal generated by accessing the memory cell MC. The generated signal may include voltage or current. Accordingly, the sense amplifier 25 may include a voltage sense amplifier, a current sense amplifier, or both.

For example, a voltage may be applied to the memory cell MC. The magnitude of the current generated by the applied voltage may depend on the resistance of the memory cell MC. Similarly, a current may be applied to the memory cell MC. The magnitude of the voltage for generating the current may depend on the resistance of the memory cell MC. The sense amplifier 25 may include various transistors or amplifiers for detecting and amplifying a signal. The sense amplifier 25 may also be referred to as latching. Subsequently, the detected logic state of the memory cell MC may be output through an input/output device. For example, the sense amplifier 25 may be a part of the column decoder 30 or the row decoder 20. Alternatively, the sense amplifier 25 may be connected to or in communication with the column decoder 30 or the row decoder 20.

The memory cell MC may be programmed or written by activating the first conductive line 10 and the second conductive line 15. A logic value may be stored in the memory cell MC. The column decoder 30 or the row decoder 20 may receive data, for example, input/output 35, to be written to the memory cell MC. In the case of a phase-change memory or a magnetic-selected memory, the memory cell MC may be written by heating the information storage element, for example, by passing a current through the memory storage element. Depending on the logic state written to the memory cell MC, for example, logic “1” or logic “0”, selenium (Se) ions may be concentrated on a specific electrode.

For example, depending on the polarity of the memory cell MC, selenium (Se) ions densely concentrated on the first electrode may generate a first threshold voltage indicating the state of logic “1”. Selenium (Se) ions densely concentrated in the second electrode may generate a second threshold voltage indicating the state of logic “0”. The first threshold voltage and the second threshold voltage may be different from each other. As the difference between the first threshold voltage and the second threshold voltage is larger, the semiconductor memory device may be more reliable.

The controller 40 may control the operation (read, write, rewrite, refresh, discharge, etc.) of the memory cells MC through various components, such as the row decoder 20, the column decoder 30, and the sense amplifier 25. In some embodiments, one or more of the row decoder 20, the column decoder 30, and/or the sense amplifier 25 may be arranged together with the controller 40. The controller 40 may generate row and column address signals to activate the desired first conductive line 10 and second conductive line 15. The controller 40 may also generate and control various voltages or currents used during the operation of the memory array. For example, the controller 40 may apply a discharge voltage to the first conductive line 10 or the second conductive line 15 after accessing one or more memory cells MC.

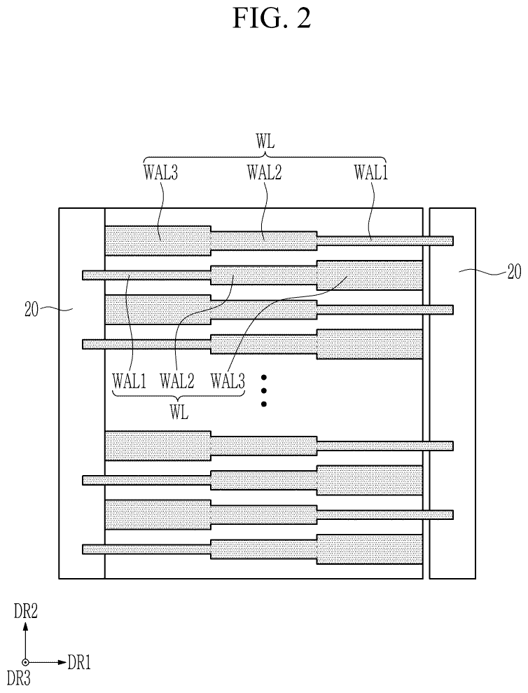

FIG. 2 is a simplified schematic diagram illustrating a planar shape of the row decoder 20 and the word line WL in the embodiments of FIG. 1. The word line WL of FIG. 2 may be the first conductive line 10 of FIG. 1.

As illustrated in FIG. 2, the row decoders 20 may be positioned on opposite sides of the word line WL, and the word lines WL adjacent in the second direction DR2 may each be connected to a different row decoder 20. That is, half of the word lines WL may be connected to the row decoder 20 positioned on the left side and half of the word lines WL may be connected to the row decoder 20 positioned on the right side, as illustrated in FIG. 2. The word line WL may extend along the first direction DR1, and the adjacent word lines WL in the second direction DR2 may be connected to different row decoders 20. For example, starting from an uppermost word line WL in the second direction D2, a word line WL positioned on an odd row may be connected to a row decoder 20 positioned on the right side, and a word line WL positioned on an even row may be connected to a row decoder 20 positioned on the left side.

As illustrated in FIG. 2, each word line WL may include a first portion WAL1, a second portion WAL2, and a third portion WAL3 having different widths. The first portion WAL1 of the word line WL may have the smallest width in the second direction DR2, the third portion WAL3 may have the widest width in the second direction DR2, and the second portion WAL2 may have a width in the second direction DR2 between the width of the first portion WAL1 and the width of the third portion WAL3. The word line WL may be connected with the row decoder 20 at the first portion WAL1. That is, the portion of the word line WL having the smallest width, i.e., the first portion WAL1, may be connected with the row decoder 20.

As illustrated in FIG. 2, the word lines WLs adjacent to each other in the second direction DR2 may be arranged such that the order of placement of the first portion WAL1, the second portion WAL2, and the third portion WAL3 is reversed. That is, referring to FIG. 2, the first portion WAL1 and the third portion WAL3 of different word lines WLs may be alternately positioned along the second direction DR2 in the plane. By positioning the narrower first portion WAL1 and the wider third portion WAL3 alternate in the plane, the plurality of word lines WLs may be effectively arranged in the plane.

As will be described separately hereinafter, the semiconductor memory device according to embodiments of the present disclosure are characterized in that the width of the word line WLs is formed differently in each region in the plane, thereby suppressing the formation of parasitic paths in the semiconductor memory device and improving reliability. In addition, the width of the third portion WAL3, which is positioned far from the row decoder 20 and has relatively high resistance, may be made wider to reduce wiring resistance and to keep the threshold voltage Vth of the word line WL uniform for each region. Specific effects will be described later.

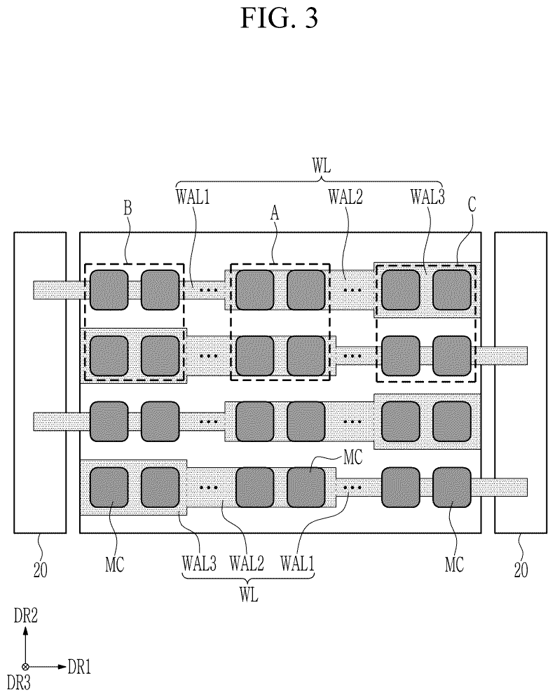

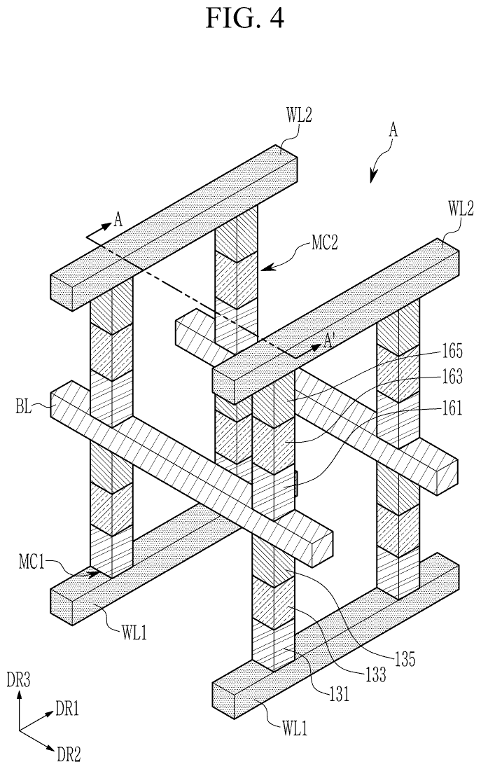

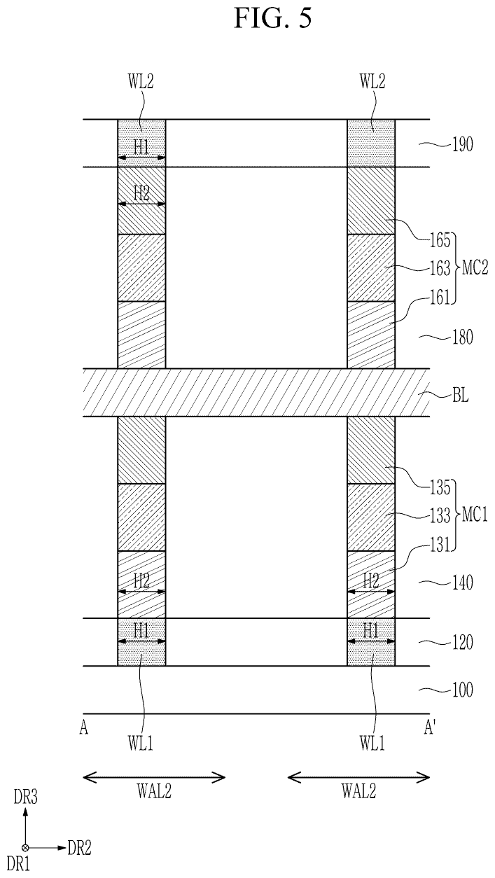

FIG. 3 is a diagram illustrating a configuration of the memory cell MC of FIG. 2. The memory cell MC may include a first electrode, a second electrode, and an OTS film positioned between the first electrode and the second electrode, as will be described separately hereinafter. The specific structure of the memory cell MC will be described later with reference to FIGS. 4 and 5. Referring to FIG. 3, the overlapping area of the word line WL and the memory cell MC may vary for each region. For example, the area of the overlapping portion of the first portion WAL1 of the word line WL and the memory cell MC may be smaller than the area of the overlapping portion of the second portion WAL2 of the word line WL and the memory cell MC.

That is, the in-plane width of the memory cell MC may be larger than the width of the first portion WAL1 of the word line WL, as illustrated in FIG. 3. Therefore, in the corresponding region, some regions of the memory cell MC may not overlap the word line WL. Also, the width of the second portion WAL2 of the word line WL and the in-plane width of the memory cell MC may be substantially the same. Also, the width of the third portion WAL3 of the word line WL may be wider than the in-plane width of the memory cell MC. Thus, some regions of the third portion WAL3 of the word line WL may not overlap the memory cell MC.

Referring now to FIGS. 4 and 5, a semiconductor memory device according to some embodiments will be described below. It is illustrated that the semiconductor memory device according to embodiments is a magnetic-selected memory, but embodiments of the present invention are not limited thereto.

FIG. 4 is a perspective view of a portion indicated by A in FIG. 3. FIG. 5 is a cross-sectional view taken along line A-A′ in FIG. 4. Referring now to FIGS. 4 and 5, the semiconductor memory device according to embodiments may include a substrate 100, a first word line WL1, a bit line BL, a second word line WL2, a first memory cell MC1, and a second memory cell MC2. FIGS. 4 and 5 illustrate a configuration in which the word line WL includes the first word line WL1 and the second word line WL2 and includes two memory cells MC1 and MC2, but this is an example and the number of word lines and memory cells may vary in different embodiments. For example, in other embodiments, the semiconductor memory device may include one word line and one memory cell. Such embodiments may include a first word line WL1 and a first memory cell MC1 as illustrated in FIGS. 4 and 5, and may not include a second memory cell MC2 and a second word line WL2.

Hereinafter, the semiconductor memory device according to present embodiments will be described with reference to FIGS. 4 and 5.

The substrate 100 may be a semiconductor substrate. For example, the substrate 100 may be bulk silicon or silicon-on-insulator (SOI). The substrate 100 may be a silicon substrate or may include other materials, such as silicon germanium, indium antimonide, lead telluride compounds, indium arsenide, indium phosphide, gallium arsenide, or gallium antimonide. Alternatively, the substrate 100 may be a substrate in which an epilayer is formed on a base substrate.

On the substrate 100, a first word line WL1, a bit line BL, and a second word line WL2 may be positioned.

The first word line WL1 may extend in the first direction DR1. At least one or more first word lines WL1 may be provided. Each of the first word lines WL1 may be spaced apart from each other in a second direction DR2. In the present specification, the first direction DR1, the second direction DR2, and the third direction DR3 may intersect each other. The first direction DR1, the second direction DR2, and the third direction DR3 may be substantially perpendicular to each other. The first word line WL1 may be the first conductive line 10 of FIG. 1. That is, the first word line WL1 of FIGS. 4 and 5 may be the word line WL of FIGS. 2 and 3.

The bit line BL may be positioned on the first word line WL1. At least one or more bit lines BL may be provided. Each bit line BL may be spaced apart from the first word line WL1 in the third direction DR3. Each bit line BL may extend in the second direction DR2. Each bit line BL may be spaced apart from each other in the first direction DR1.

The bit line BL may be the second conductive line 15 of FIG. 1.

The second word line WL2 may be positioned on the bit lines BL. At least one or more second word lines WL2 may be provided. Each second word line WL2 may be spaced from the first word line WL1 and the bit line BL in the third direction DR3. Each of the second word lines WL2 may extend in the first direction DR1. Each of the second word lines WL2 may be spaced apart from each other in the second direction DR2.

The second word line WL2 may be the first conductive line 10 of FIG. 1. The second word line WL2 of FIGS. 4 and 5 may be the word line WL of FIGS. 2 and 3.

In some embodiments, the first word line WL1 and the second word line WL2 may each extend in the first direction DR1 and the bit line BL may extend in the second direction DR2. The bit line BL may be interposed between the first word line WL1 and the second word line WL2.

The first word line WL1, the second word line WL2, and the bit line BL may each include a conductive material. For example, the first word line WL1, the second word line WL2, and the bit line BL may each include at least one of, but not limited to, tungsten (W), tungsten nitride (WN), gold (Au), silver (Ag), copper (Cu), aluminum (Al), titanium aluminum nitride (TiAlN), nickel (Ni), cobalt (Co), chromium (Cr), tin (Sn), zinc (Zn), indium tin oxide (ITO), and/or combinations thereof.

The first word line WL1, the second word line WL2, and the bit line BL may include the same material or may include different materials. In embodiments, the first word line WL1, the second word line WL2, and the bit line BL may each include tungsten (W).

In embodiments, referring to FIG. 5, a first interlayer insulation film 120 may be provided between the first word lines WL1. The first interlayer insulation film 120 may be disposed on the substrate 100. The first interlayer insulation film 120 may be interposed between the first word lines WL1 to insulate each of the first word lines WL1.

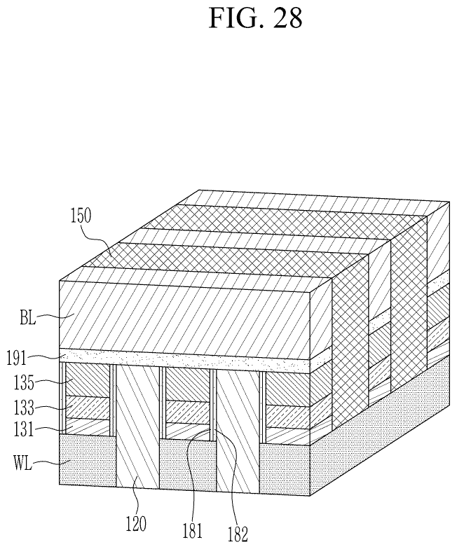

Additionally, although not illustrated in FIGS. 4 and 5, a second interlayer insulation film may be provided between the respective bit lines BL. The second interlayer insulation film may be provided on the first memory cells MC1. The second interlayer insulation film may be interposed between the bit lines BL to insulate the respective bit lines BL. FIG. 28 illustrates a second interlayer insulation film 150 positioned between the bit lines BL.

A third interlayer insulation film 190 may be provided between the second word lines WL2. The third interlayer insulation film 190 may be provided on the second memory cell MC2. The third interlayer insulation film 190 may be interposed between the second word lines WL2 to insulate each of the second word lines WL2.

Each of the first to third interlayer insulation films 120, 150, and 190 may include an oxide-based insulating material. For example, the first to third interlayer insulation films 120, 150, and 190 may each include at least one of, but not limited to, silicon oxide, silicon oxynitride, and/or a low-k material having a dielectric constant smaller than silicon oxide.

The first memory cell MC1 may be provided between the first word line WL1 and the bit line BL. The first memory cell MC1 may be disposed at an intersection of the first word line WL1 and the bit line BL. One end of the first memory cell MC1 may be connected to a word line of the semiconductor memory device. The other end of the first memory cell MC1 may be connected to a bit line of the semiconductor memory device. At least one first memory cell MC1 may be provided. Each of the first memory cells MC1 may be spaced apart in the first direction DR1, and each of the first memory cells MC1 may be spaced apart in the second direction DR2. The first memory cells MC1 may extend in the third direction DR3.

In embodiments, the first memory cell MC1 may include a first electrode 131, a first OTS film 133, and a second electrode 135.

The first electrode 131, the first OTS film 133, and the second electrode 135 may be sequentially aligned in the third direction DR3. The first electrode 131 may be disposed on the first word line WL1. The first OTS film 133 may be disposed on the first electrode 131. The second electrode 135 may be disposed on the first OTS film 133. The first OTS film 133 may be interposed between the first electrode 131 and the second electrode 135.

The first electrode 131 may be in contact with the first word line WL1. The first electrode 131 may include a conductive material. For example, the first electrode 131 may include carbon (C). Alternatively, the first electrode 131 may include at least one of a metal such as tungsten (W), platinum (Pt), palladium (Pd), rhodium (Rh), ruthenium (Ru), iridium (Ir), copper (Cu), aluminum (Al), titanium (Ti), tantalum (Ta), a metal nitride such as titanium nitride (TiN), and/or combinations thereof.

The second electrode 135 may be provided on the first electrode 131. The second electrode 135 may be in contact with the bit line BL. The second electrode 135 may include a conductive material. For example, the second electrode 135 may include carbon (C). Alternatively, the second electrode 135 may include at least one of a metal such as tungsten (W), platinum (Pt), palladium (Pd), rhodium (Rh), ruthenium (Ru), iridium (Ir), copper (Cu), aluminum (Al), titanium (Ti), tantalum (Ta), a metal nitride such as titanium nitride (TiN), and/or combinations thereof.

The first OTS film 133 may be provided between the first electrode 131 and the second electrode 135. The first OTS film 133 may be connected to the first electrode 131 and the second electrode 135. In some embodiments, the first OTS film 133 may function as an information storage element for the first memory cell MC1. The first OTS film 133 may include a chalcogenide material. The chalcogenide material may include a compound in which at least one of chalcogen elements S, Te, and/or Se is combined with at least one of Ge, Sb, Bi, Al, Tl, Sn, Zn, As, Si, In, Ti, Ga, and/or P.

For example, the first OTS film 133 may include at least one of GeSe, GeS, AsSe, AsTe, AsS, SiTe, SiSe, SiS, GeAs, SiAs, SnSe, SnTe, GeAsTe, GeAsSe, AlAsTe, AlAsSe, SiAsSe, SiAsTe, GeSeTe, GeSeSb, GaAsSe, GaAsTe, InAsSe, InAsTe, SnAsSe, SnAsTe, GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, GeAsTeZn, GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, GeAsSeTlSn, GeAsSeZnSn, GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeSsSeSGaZn, GeAsSeSGasS, and/or GeAsSeSAlSn.

The semiconductor memory device according to embodiments may store data via the movement of ions contained in the first OTS film 133. The logic state of the data stored in the first OTS film 133 may be based on the polarity of the program voltage. For example, when a voltage is applied to the first electrode 131 and the second electrode 135, ions contained in the first OTS film 133 may move toward the first electrode 131 and the second electrode 135. For example, the first OTS film 133 may include selenium (Se) ions. When a voltage is applied to the first electrode 131 and the second electrode 135, the selenium (Se) ions in the first OTS film 133 may move toward the first electrode 131 or the second electrode 135.

For example, depending on the polarity of the first memory cell MC1, selenium (Se) ions densely concentrated at the first electrode 131 may generate a first threshold voltage indicative of the state of logic “1”. Depending on the polarity of the first memory cell MC1, selenium (Se) ions densely concentrated at the second electrode 135 may generate a second threshold voltage indicative of the state of logic “0”. The first threshold voltage and the second threshold voltage may be different from each other. As the difference between the first threshold voltage and the second threshold voltage is larger, the semiconductor memory device may be more reliable.

FIGS. 4 and 5 illustrate a configuration in which the first memory cell MC1 is rectangular in cross-section, i.e., the widths of the first electrode 131, the second electrode 135, and the first OTS film 133 are constant in cross-section, but this is an example, and in other embodiments, the widths of the first electrode 131, the second electrode 135, and the first OTS film 133 may gradually decrease as being away from the substrate 100. In other words, the first electrode 131, the second electrode 135, and the first OTS film 133 may have a trapezoidal shape, in terms of cross-sectional area. Additionally, some of the components configuring the memory cell MC may have a trapezoidal shape in cross-section. For example, the first OTS film 133 may have a trapezoidal cross-section, while the first electrode 131 and the second electrode 135 may have a square cross-section. These other embodiments will be described separately hereinafter.

The semiconductor memory device according to embodiments may further include a first cell insulation film 140. The first cell insulation film 140 may surround the first memory cell MC1. The first cell insulation film 140 may electrically insulate the first memory cell MC1.

The first cell insulation film 140 may include an oxide-based insulating material. For example, the first cell insulation film 140 may include at least one of silicon oxide, silicon carbon oxide, and a low thermal conductivity material having a lower thermal conductivity than silicon oxide.

For example, the first cell insulation film 140 may include at least one of SiO₂, SiOC, Spin-On glass (SOG), Spin-On Dielectric (SOD), High Density Plasma (HDP) oxide, Flowable Oxide (FOX), Torene SilaZene (TOSZ), Undoped Silica glass (USG), Borosilica glass (BSG), PhosphoSilica glass (PSG), BoroPhosphoSilica glass (BPSG), tetra-ethyl OrthoSilicate (TEOS), Plasma Enhanced tetra-ethyl Ortho Silicate (PETEOS), Fluoride silicate glass (FSG), Carbon Doped silicon Oxide (CDO), Xerogel, Aerogel, Amorphous Fluorinated Carbon, Organo silicate glass (OSG), Parylene, bis-benzocyclobutenes (BCB), SiLK, polyimide, porous polymeric material, and/or combination thereof, but is not limited thereto. In some embodiments, the first cell insulation film 140 may be flowable oxide (FOX).

The second memory cell MC2 may be provided between the bit line BL and the second word line WL2. The second memory cell MC2 may be disposed at the intersection of the bit line BL and the second word line WL2. One end of the second memory cell MC2 may be connected to a word line of the semiconductor memory device. The other end of the second memory cell MC2 may be connected to a bit line of the semiconductor memory device. At least one second memory cell MC2 may be provided. Each of the second memory cells MC2 may be spaced apart in the first direction DR1, or may be spaced apart in the second direction DR2. The second memory cells MC2 may extend in the third direction DR3.

In embodiments, the second memory cell MC2 may include a third electrode 161, a second OTS film 163, and a fourth electrode 165. The third electrode 161, the second OTS film 163, and the fourth electrode 165 may be sequentially aligned in the third direction DR3. The third electrode 161 may be disposed on the bit line BL. The second OTS film 163 may be disposed on the third electrode 161. The fourth electrode 165 may be disposed on the second OTS film 163.

The third electrode 161 may be in contact with the bit line BL. The third electrode 161 may include a conductive material. For example, the third electrode 161 may include carbon (C). Alternatively, the third electrode 161 may include at least one of a metal such as tungsten (W), platinum (Pt), palladium (Pd), rhodium (Rh), ruthenium (Ru), iridium (Ir), copper (Cu), aluminum (Al), titanium (Ti), tantalum (Ta), a metal nitride such as titanium nitride (TiN), and/or combinations thereof.

The fourth electrode 165 may be provided on the third electrode 161. The fourth electrode 165 may be in contact with the second word line WL2. The fourth electrode 165 may include a conductive material. For example, the fourth electrode 165 may include carbon (C). Alternatively, the fourth electrode 165 may include at least one of a metal such as tungsten (W), platinum (Pt), palladium (Pd), rhodium (Rh), ruthenium (Ru), iridium (Ir), copper (Cu), aluminum (Al), titanium (Ti), tantalum (Ta), a metal nitride such as titanium nitride (TiN), and/or combinations thereof.

The second OTS film 163 may be provided between the third electrode 161 and the fourth electrode 165. The second OTS film 163 may be provided between the third electrode 161 and the fourth electrode 165. The second OTS film 163 may be connected to the third electrode 161 and the fourth electrode 165. In some embodiments, the second OTS film 163 may function as an information storage element for the second memory cell MC2. The second OTS film 163 may include a chalcogenide material. The chalcogenide material may include a compound in which at least one of chalcogen elements S, Te, and Se is combined with at least one of Ge, Sb, Bi, Al, Tl, Sn, Zn, As, Si, In, Ti, Ga, and/or P.

For example, the second OTS film 163 may include at least one of GeSe, GeS, AsSe, AsTe, AsS, SiTe, SiSe, SiS, GeAs, SiAs, SnSe, SnTe, GeAsTe, GeAsSe, AlAsTe, AlAsSe, SiAsSe, SiAsTe, GeSeTe, GeSeSb, GaAsSe, GaAsTe, InAsSe, InAsTe, SnAsSe, SnAsTe, GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, GeAsTeZn, GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, GeAsSeTlSn, GeAsSeZnSn, GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and/or GeAsSeSAlSn.

The semiconductor memory device according to embodiments may store data via the movement of ions contained in the second OTS film 163. The logical state of the data stored in the second OTS film 163 may be based on the polarity of the program voltage. For example, when a voltage is applied to the third electrode 161 and the fourth electrode 165, the ions contained in the second OTS film 163 may move toward the third electrode 161 or the fourth electrode 165. For example, the second OTS film 163 may include selenium (Se) ions. When a voltage is applied to the third electrode 161 and the fourth electrode 165, the selenium (Se) ions in the second OTS film 163 may move toward the third electrode 161 or the fourth electrode 165.

For example, depending on the polarity of the second memory cell MC2, selenium (Se) ions densely concentrated at n the third electrode 161 may generate the first threshold voltage indicative of the state of logic “1”. Depending on the polarity of the second memory cell MC2, selenium (Se) ions densely concentrated on the fourth electrode 165 may generate the second threshold voltage indicative of the state of logic “0”. The first threshold voltage and the second threshold voltage may be different from each other. As the difference between the first threshold voltage and the second threshold voltage is larger, the semiconductor memory device may have improved reliability.

FIGS. 4 and 5 illustrate a configuration in which the second memory cell MC2 has a rectangular cross-section, i.e., a configuration in which the widths of the third electrode 161, the fourth electrode 165, and the second OTS film 163 are constant in cross-section, but this is an example, and in other embodiments, the widths of the third electrode 161, the fourth electrode 165, and the second OTS film 163 may gradually decrease as being away from or closer to the substrate 100. That is, the third electrode 161, the fourth electrode 165, and the second OTS film 163 may have a trapezoidal shape, in terms of cross-sectional area. Additionally, some of the components configuring the memory cell MC may have a trapezoidal shape in cross-section. For example, the second OTS film 163 may have a trapezoidal cross-section, and the third electrode 161 and the fourth electrode 165 may have a square cross-section. These other embodiments will be described separately hereinafter.

The semiconductor memory device according to some embodiments may further include a second cell insulation film 180. The second cell insulation film 180 may surround the second memory cell MC2. The second cell insulation film 180 may electrically insulate the second memory cell MC2.

The second cell insulation film 180 may include an oxide-based insulating material. For example, the second cell insulation film 180 may include at least one of silicon oxide, silicon carbon oxide, and a low thermal conductivity material having a lower thermal conductivity than silicon oxide.

For example, the second cell insulation film 180 may include at least one of SiO₂, SiOC, Spin-On glass (SOG), Spin-On Dielectric (SOD), High Density Plasma (HDP) oxide, Flowable Oxide (FOX), Torene SilaZene (TOSZ), Undoped Silica glass (USG), Borosilica glass (BSG), PhosphoSilica glass (PSG), BoroPhosphoSilica glass (BPSG), tetra-ethyl OrthoSilicate (TEOS), Plasma Enhanced tetra-ethyl Ortho Silicate (PETEOS), Fluoride silicate glass (FSG), Carbon Doped silicon Oxide (CDO), Xerogel, Aerogel, Amorphous Fluorinated Carbon, Organo silicate glass (OSG), Parylene, bis-benzocyclobutenes (BCB), SiLK, polyimide, porous polymeric material, and/or combination thereof, but is not limited thereto. In some embodiments, the second cell insulation film 180 may be flowable oxide (FOX).

Referring to FIGS. 4 and 5, the width H1 in the second portion WAL2 of the first word line WL1 in the second direction DR2 may be the same as the width H2 of the first electrode 131 that is in contact with the first word line WL1 in the second direction DR2. FIGS. 4 and 5 are perspective and cross-sectional views of the portion indicated by A in FIG. 3, and the portion indicated by A in FIG. 3 includes the second portion WAL2 of the word line WL. As described above, the width in the plane of the second portion WAL2 of the word line WL in the second direction DR2 may be the same as the width in the plane of the memory cell MC in the second direction DR2. Thus, as illustrated in FIGS. 4 and 5, the width H1 of the first word line WL1 may be the same as the width H2 of the first electrode 131 that is in contact with the first word line WL1. Similarly, the width H1 of the second word line WL2 may be the same as the width H2 of the fourth electrode 165 that is in contact with the second word line WL2.

As described above, the semiconductor memory device according to present embodiments has different widths of the word lines WL for each region. Therefore, the widths of the word lines WL in different regions may be different. The word lines WL in different regions are described below.

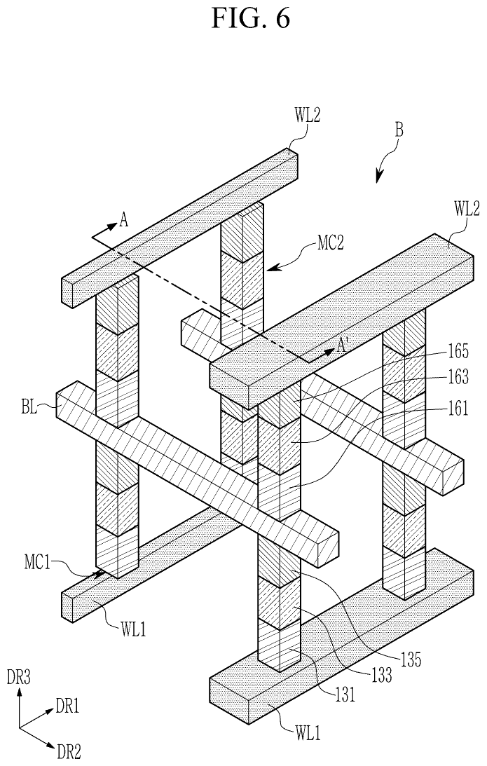

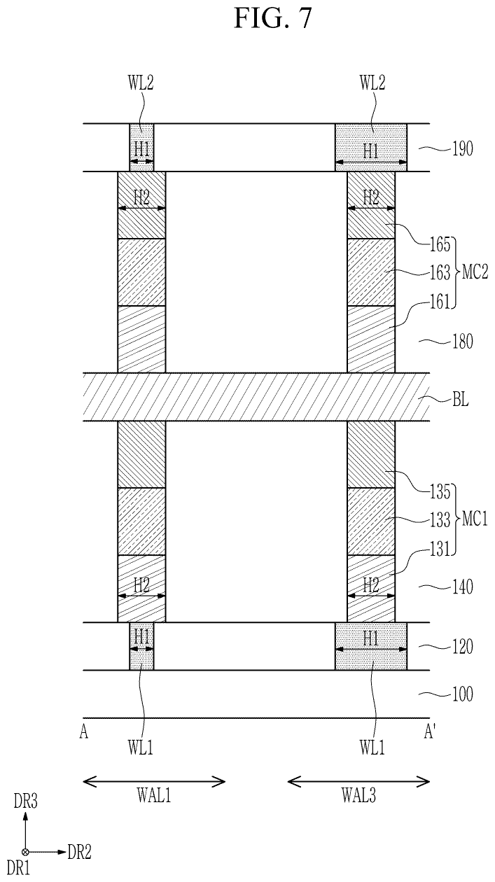

FIG. 6 is a perspective view of a portion indicated by B in FIG. 3, and FIG. 7 is a cross-sectional view taken along line A-A′ of FIG. 6.

Referring to FIGS. 6 and 7, the present diagrams illustrate the first portion WAL1 and the third portion WAL3 of the word lines WL1 and WL2. In this case, the width H1 of the first portion WAL1 in the second direction DR2 of the first word line WL1 may be narrower than the width H2 of the first electrode 131 in the second direction DR2 that is in contact with the first word line WL1. In other words, the width H1 in the second direction DR2 of the first word line WL1 in the first portion WAL1 may be narrower than the width H2 of the first electrode 131 in the second direction DR2 that is in contact with the first word line WL1, as illustrated in the left region of FIGS. 6 and 7. Similarly, as illustrated in the left region of FIGS. 6 and 7, the width H1 in the second direction DR2 of the second word line WL2 in the first portion WAL1 may be narrower than the width H2 of the fourth electrode 165 in the second direction DR2 that is in contact with the second word line WL2. In this way, since the width H1 of the first word line WL1 in the first portion WAL1 is narrower than the width H2 of the first electrode 131, the formation of parasitic paths in the memory cell MC may be suppressed. The specific effect will be described separately hereinafter.

Furthermore, the width H1 in the second direction DR2 of the first word line WL1 in the third portion WAL3 may be wider than the width H2 of the first electrode 131 in the second direction DR2 that is in contact with the first word line WL1, as illustrated in the right region of FIGS. 6 and 7. Similarly, as illustrated in the right region of FIGS. 6 and 7, the width H1 in the second direction DR2 of the second word line WL2 in the third portion WAL3 may be wider than the width H2 in the second direction DR2 of the fourth electrode 165 that is in contact with the second word line WL2. This may reduce the resistance of the word line. That is, the resistance of the word line increases in the third portion WAL3, which is positioned farther away from the row decoder 20 as illustrated in FIGS. 2 and 3, and the resistance may be reduced by widening the width of the word line in the third portion WAL3.

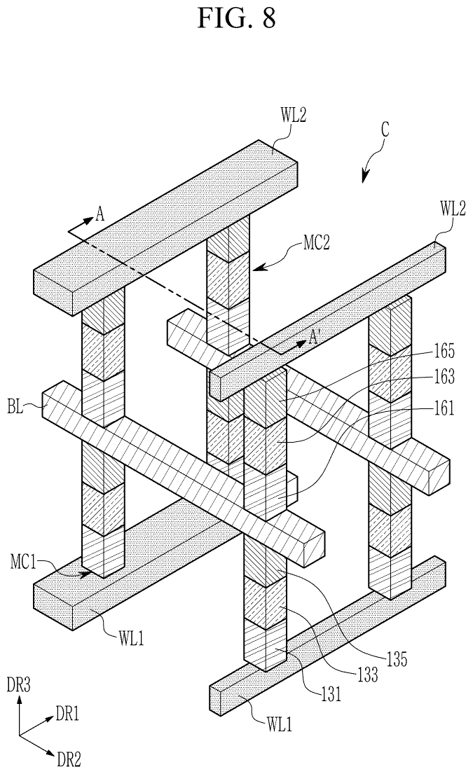

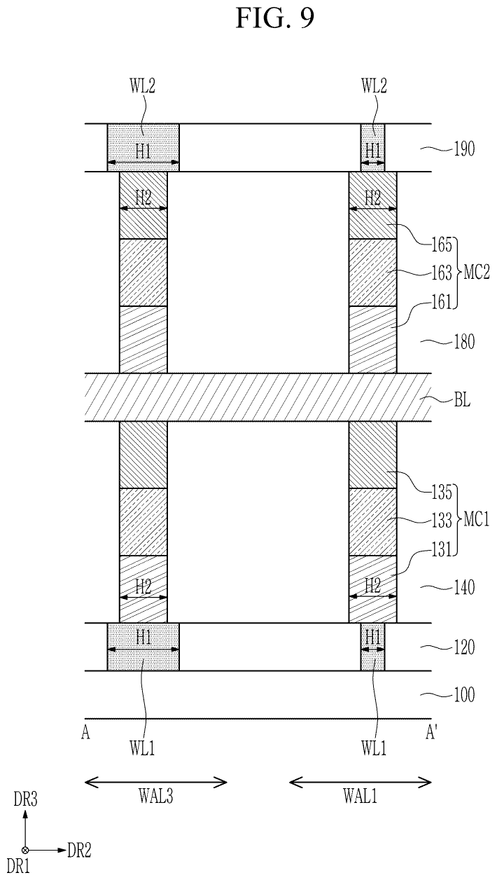

FIG. 8 is a perspective view of a portion indicated by C of FIG. 3, and FIG. 9 is a cross-sectional view taken along line A-A′ of FIG. 8.

Referring now to FIGS. 8 and 9, the present diagrams illustrate the first portion WAL1 and the third portion WAL3 of the word lines WL1 and WL2. In this case, the width H1 in the second direction DR2 of the third portion WAL3 of the first word line WL1 may be wider than the width H2 in the second direction DR2 of the first electrode 131 that is in contact with the first word line WL1. In other words, the width H1 in the second direction DR2 of the first word line WL1 in the third portion WAL3 may be wider than the width H2 in the second direction DR2 of the first electrode 131 that is in contact with the first word line WL1, as illustrated in the left region of FIGS. 8 and 9. Similarly, as illustrated in the left region of FIGS. 8 and 9, the width H1 in the second direction DR2 of the second word line WL2 in the third portion WAL3 may be wider than the width H2 in the second direction DR2 of the fourth electrode 165 that is in contact with the second word line WL2. This may reduce the resistance of the word line. That is, the resistance of the word line increases in the third portion WAL3, which is positioned farther away from the row decoder 20 as illustrated in FIGS. 2 and 3, and the resistance may be reduced by widening the width of the word line in the third portion WAL3.

Furthermore, the width H1 in the second direction DR2 of the first word line WL1 in the first portion WAL1 may be narrower than the width H2 in the second direction DR2 of the first electrode 131 that is in contact with the first word line WL1, as illustrated in the right region of FIGS. 8 and 9. Similarly, as illustrated in the right region of FIGS. 8 and 9, the width H1 in the second direction DR2 of the second word line WL2 in the first portion WAL1 may be narrower than the width H2 in the second direction DR2 of the fourth electrode 165 that is in contact with the second word line WL2. In this way, since the width H1 of the first word line WL1 in the first portion WAL1 is narrower than the width H2 of the first electrode 131, the formation of a parasitic path may be suppressed, as will be described separately hereinafter.

That is, referring simultaneously to FIGS. 3 to 9, the first portion WAL1, the second portion WAL2, and the third portion WAL3 of one first word line WL1 have different widths. By forming different widths of the first word line WL1 for each region, the formation of parasitic paths may be suppressed and resistance reduced. Similarly, the first portion WAL1, the second portion WAL2, and the third portion WAL3 of the second word line WL2 may also have different widths. However, although FIGS. 4 to 9 illustrate a configuration in which the word line includes the first word line WL1 and the second word line WL2, this is an example, and in some embodiments, the word line may include the first word line WL1 and not include the second word line WL2. In other words, a semiconductor memory device according to some embodiments may include the first memory cell MC1 and not include the second memory cell MC2.

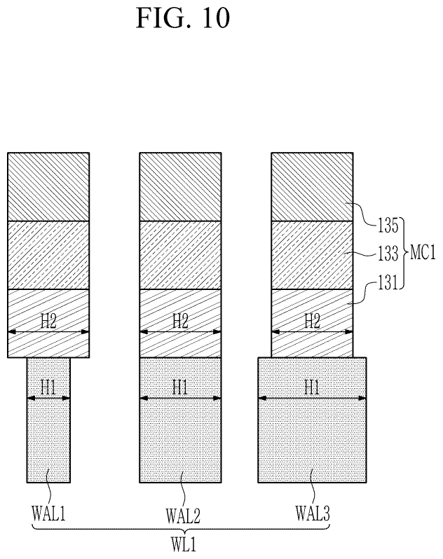

FIG. 10 is a simplified cross-sectional view of the first word line WL1 and the first memory cell MC1. FIG. 10 illustrates cross-sections at the first portion WAL1, the second portion WAL2, and the third portion WAL3 of the first word line WL1. The first memory cell MC1 includes the first electrode 131, the first OTS film 133, and the second electrode 135.

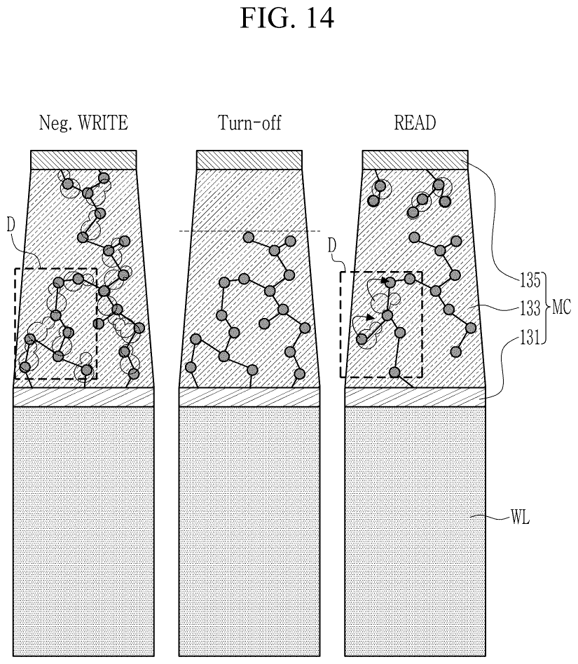

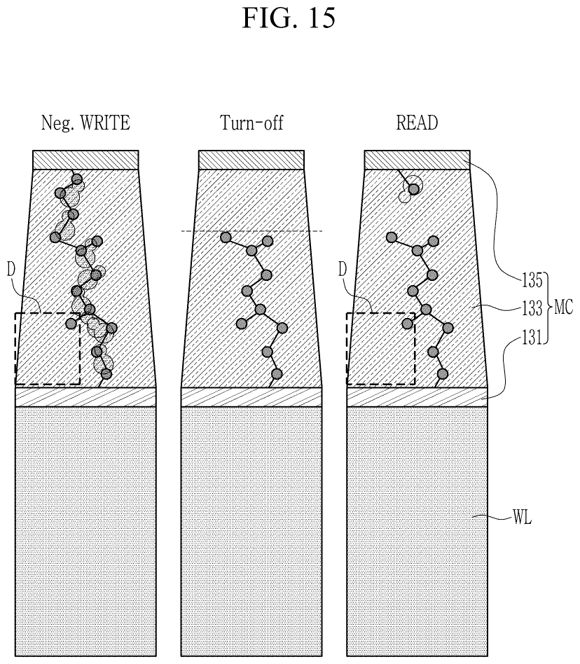

Referring to FIG. 10, the width H1 of the first portion WAL1 of the first word line WL1 may be narrower than the width H2 of the first electrode 131 of the first memory cell MC1. Since the width H1 of the first portion WAL1 is narrower than the width H2 of the first electrode 131, the area in which the first electrode 131 is in contact with the word line is reduced. This may suppress the formation of parasitic paths, thereby improving dipole flipping and improving endurance characteristics. Specific effects will be described later with reference to FIGS. 14 and 15.

Also, the width H1 of the second portion WAL2 of the first word line WL1 and the width H2 of the first electrode 131 may be the same. The width H1 of the third portion WAL3 of the first word line WL1 may be larger than the width H2 of the first electrode 131. The third portion WAL3 may have increased wiring resistance in areas farther away from the row decoder 20. If the wiring resistance varies by region of the word line in this way, Vth Skew may occur, and there may be a problem that the reliability of the wiring varies by region due to spike currents. However, the semiconductor memory device according to the present embodiment may solve these problems by reducing the wiring resistance by forming a wide width of the third portion WAL3 of the first word line WL1.

FIGS. 4 to 10 previously illustrated the configuration in which the word lines and the memory cells have a square cross-section, but this is only an example and the cross-section of the word line and the memory cell may vary. That is, in some embodiments, the cross-section of the first memory cell MC1 may be trapezoidal. For example, the first electrode 131, the second electrode 135, and the first OTS film 133 may have a trapezoidal shape in which, in terms of cross-sectional area, the length of the side adjacent to the first word line WL1 between the two parallel sides is longer than the length of the side adjacent to the bit line BL. Alternatively, the cross-sections of the first electrode 131 and the second electrode 135 may be rectangular and the cross-section of the first OTS film 133 may be trapezoidal,

That is, the cross-section of the first OTS film 133 may have a trapezoidal shape such that the length of the side adjacent to the second electrode 135 between the two parallel sides is smaller than the length of the side adjacent to the first electrode 131.

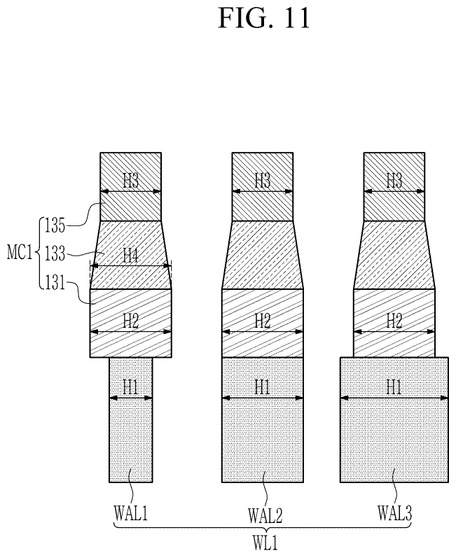

FIG. 11 is a diagram illustrating the same area as FIG. 10 for other embodiments. Referring to FIG. 11, the first memory cell MC1 is identical to embodiments of FIG. 10 except that the shape of the first memory cell MC1 is different. Specific description of the same components is omitted.

Referring to FIG. 11, the width H2 of the first electrode 131 may be wider than the width H3 of the second electrode 135. Further, the cross-section of the first OTS film 133 may be trapezoidal. That is, the cross-section of the first OTS film 133 may be trapezoidal in shape such that the length of the side adjacent to the second electrode 135 between the two parallel sides is smaller than the length of the side adjacent to the first electrode 131. In this case, the length of the side adjacent to the first electrode 131 of the first OTS film 133 may be equal to the width H2 of the first electrode 131, and the length of the side adjacent to the second electrode 135 may be equal to the width H3 of the second electrode 135.

In the previous embodiments, the width of the first electrode 131 of the first memory cell MC1 was the same for all regions, but in embodiments, the width of the first electrode 131 of the first memory cell MC1 may vary for each region of the word line.

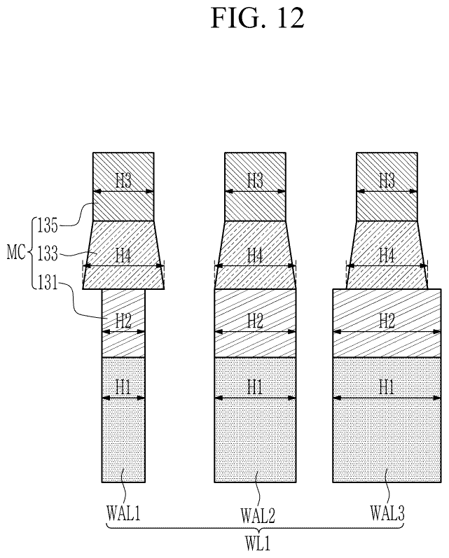

FIG. 12 is a diagram illustrating the same area as FIG. 11 for other embodiments. Referring to FIG. 12, the semiconductor memory device according to present embodiments is the same as embodiments of FIG. 11 except that the width of the first electrode 131 of the first memory cell MC1 is different for each region (WAL1, WAL2, and WAL3) of the first word line. Specific description of the same components is omitted.

Referring to FIG. 12, the width H1 of the first portion WAL1 of the first word line WL1 and the width H2 of the first electrode 131 that is in contact with the first word line WL1 are the same. Further, the width H1 of the second portion WAL2 of the first word line WL1 and the width H2 of the first electrode 131 that is in contact with the first word line WL1 are the same. Furthermore, the width H1 of the third portion WAL3 of the first word line WL1 and the width H2 of the first electrode 131 that is in contact with the first word line WL1 are the same. Since the widths of the first portion WAL1, the second portion WAL2, and the third portion WAL3 of the first word line WL1 are different, the width of the first electrodes 131 that is in contact with the first word line WL1 may also be different for each region. That is, the width H2 of the first electrode 131 that is in contact with the first portion WAL1 of the first word line WL1 may be narrower than the width H2 of the first electrode 131 that is in contact with the second portion WAL2 of the first word line WL1. Similarly, the width H2 of the first electrode 131 that is in contact with the second portion WAL2 of the first word line WL1 may be narrower than the width H2 of the first electrode 131 that is in contact with the third portion WAL3 of the first word line WL1.

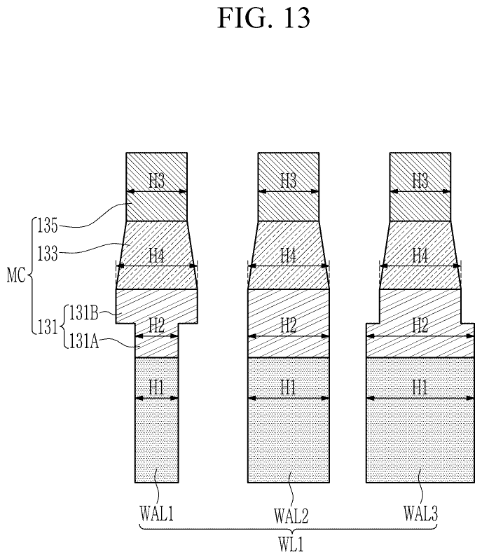

Furthermore, the width of the first electrode 131 may be different at the top and the bottom. FIG. 13 is a diagram illustrating the same area as FIG. 12 for other embodiments. FIG. 13 is identical to embodiments of FIG. 12 except that the first electrode 131 has different widths at the top and the bottom. Specific description of the same components is omitted. Referring to FIG. 13, the semiconductor memory device according to present embodiments are the same as embodiments of FIG. 12 except that the width H2 of the side that is in contact with the first word line WL1 of the first electrode 131 and the width H4 of the side that is in contact with the first OTS film 133 are different. Specific description of the same components is omitted.

Referring to FIG. 13, the semiconductor memory device according to present embodiments may include a first electrode 131 having a first portion 131A and a second portion 131B having different widths. In this case, the description of the width H2 of the first portion 131A is the same as previously described in FIG. 12. The width H1 of the first portion WAL1 of the first word line WL1 and the width H2 of the first portion 131A of the first electrode 131 that is in contact with the first word line WL1 may be the same. Similarly, the width H1 of the second portion WAL2 of the first word line WL1 and the width H2 of the first portion 131A of the first electrode 131 that is in contact with the first word line WL1 may be the same. Further, the width H1 of the third portion WAL3 of the first word line WL1 and the width H2 of the first portion 131A of the first electrode 131 that is in contact with the first word line WL1 may be the same. That is, the width of the first portion 131A of the first electrode 131 may vary for each region. However, as illustrated in FIG. 13, the width H4 of the second portion 131B of the first electrode 131 may be the same in each of the regions WAL1, WAL2, and WAL3. The width H4 of the second portion 131B of the first electrode 131 may be the same as the width of the first OTS film 133 that is in contact with the first electrode 131. That is, in each first memory cell MC1 overlapping the first word line WL1, the width H2 of the first portion 131A of the first electrode 131 may vary for each region, but the width H4 of the second portion 131B may be the same in each region.

The effect of the memory device according to present embodiments will now be described below with reference to the drawings. FIG. 14 illustrates the conduction path of the first OTS film 133 in each operation of the memory device in which the width of the first electrode 131 and the width of the word line WL are the same. Referring to FIG. 14, a conductive path may be formed in the direction from the first electrode 131 to the second electrode 135 during a negative write operation. Then, upon turning off, the conductive path may be partially annihilated at the interfacial region of the second electrode 135. Next, in the case of a read operation, a read is performed from the second electrode 135 in the direction toward the first electrode 131. As the read bias is applied in the opposite direction to the negative write during the read operation, the unstable bond may be reversed, which may cause deterioration. The area where such an unstable bond is formed and deterioration occurs is indicated by D in FIG. 15.

However, the memory device according to present embodiments reduces the area in which the word line WL is in contact with the memory cell MC, thereby reducing unstable bonds and the formation of parasitic path. FIG. 15 illustrates the conductive path of the first OTS film 133 during each operation in the memory device having a narrower width of the word line WL than the width of the first electrode 131. Comparing the negative write operation of FIG. 14 with the negative write operation of FIG. 15, a parasitic path is formed in the region indicated by D in FIG. 14. However, in the same region in FIG. 15, the first electrode 131 is not in contact with the word line WL, so no parasitic path is formed. In other words, the formation of a parasitic path is suppressed, and thus the dipole flip in the read operation is improved, which may improve the endurance characteristics.

A manufacturing method of a memory device according to present embodiments will now be described in detail with reference to the following drawings. However, the manufacturing method described below is only an example, and embodiments of the present invention are not limited thereto.

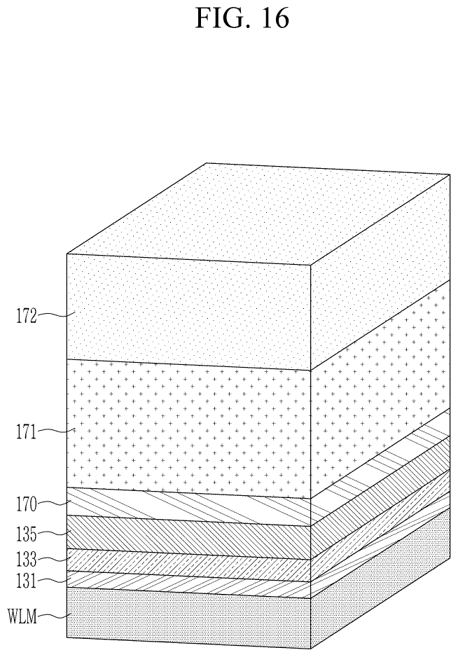

FIGS. 16 to 28 are diagrams illustrating a method of manufacturing a memory device according to embodiments. Referring to FIG. 16, a word line metal layer WLM, a first electrode 131, a first OTS film 133, a second electrode 135, a first insulation film 170, a second insulation film 171, and a first patterning film 172 are formed in sequence. In this case, the descriptions of the materials of the word line metal layer WLM, the first electrode 131, the first OTS film 133, and the second electrode 135 are omitted because they are the same as described above. For example, the word line metal layer WLM may include tungsten, the first electrode 131 and the second electrode 135 may include carbon, and the first OTS film 133 may include a chalcogenide material. The first insulation film 170 may include a silicon nitride, and the second insulation film 171 may include a silicon oxide, but this is by way of example only and embodiments of the present invention are not limited thereto.

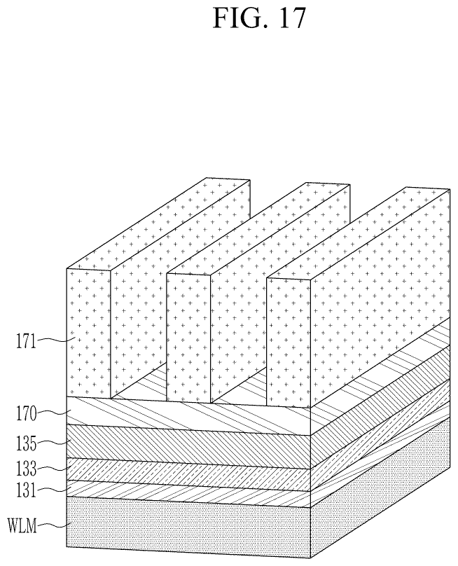

Next, referring to FIG. 17, a first patterning film 172 is patterned and the second insulation film 171 is etched by using the first patterning film 172 as a mask.

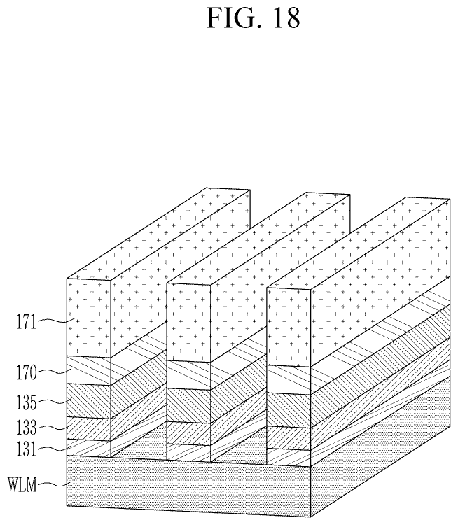

Next, referring to FIG. 18, the first electrode 131, the first OTS film 133, the second electrode 135, and the first insulation film 170 are etched by using the etched second insulation film 171 to form the first electrode 131, the first OTS film 133, and the second electrode 135.

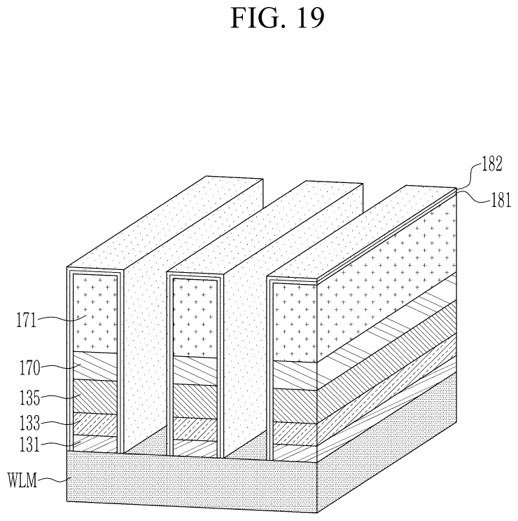

Next, referring to FIG. 19, a first sealing layer 181 and a second sealing layer 182 are formed on the etched first electrode 131, first OTS film 133, second electrode 135, first insulation film 170, and second insulation film 171. The first sealing layer 181 may include silicon nitride and the second sealing layer 182 may include silicon oxide, but this is an example only and embodiments of the invention are not limited thereto. The first sealing layer 181 and the second sealing layer 182 may be formed along the surface of the stacked first electrode 131, first OTS film 133, second electrode 135, first insulation film 170, and second insulation film 171 and may not be formed on top of the word line metal layer WLM. In embodiments, the forming process of the first sealing layer 181 and the second sealing layer 182 may be omitted.

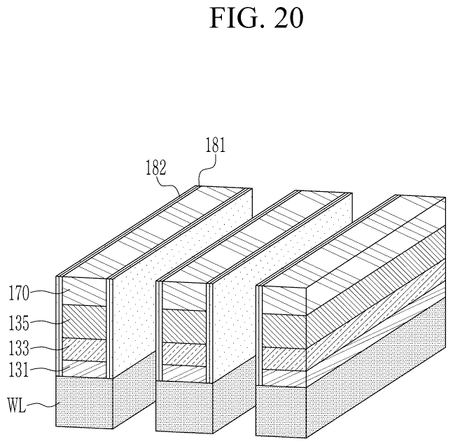

Next, referring to FIG. 20, the second insulation film 171 is removed and the word line metal layer WLM is etched to form the word line WL. In FIG. 20, it is illustrated that the width of the formed word line WL and the width of the stack of the first electrode 131, the first OTS film 133, the second electrode 135, and the first insulation film 170 are the same, but the width of the word line WL may vary for each region. In other words, the present manufacturing method represents the forming process of the second portion WAL2 of the memory device described above, and in the first portion WAL1, the width of the word line WL is formed narrower than the width of the first electrode 131 in this operation, and in the third portion WAL3, the width of the word line WL may be formed wider than the width of the first electrode 131. In the present manufacturing method, the etching process of the first electrode 131, the first OTS film 133, the second electrode 135, and the etching process of the word line metal layer WLM for forming the word line WL are separated into separate operations, so that the width of the first electrode 131 and the width of the word line WL may be formed differently.

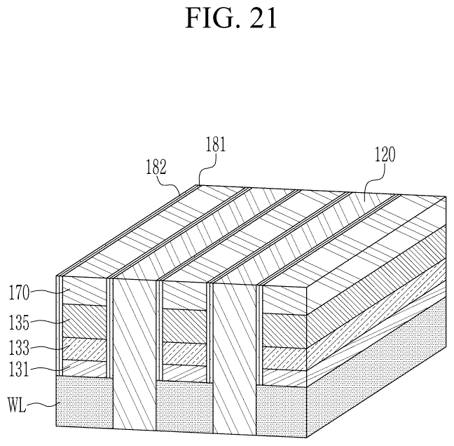

Next, referring to FIG. 21, the space between the etched word line WL and the space between the stacks of the first electrode 131, the first OTS film 133, the second electrode 135, and the first insulation film 170 may be filled with the first interlayer insulation film 120. A description of the material of the first interlayer insulation film 120 is omitted as it is the same as described above. In present embodiments, the first interlayer insulation film 120 is illustrated as filling both the space between the word lines WL and the space between the stacks of the first electrode 131, the first OTS film 133, the second electrode 135, and the first insulation film 170, but this is an example, and in other embodiments, and the space between the word lines WL and the space between the stacks of the first electrode 131, the first OTS film 133, the second electrode 135, and the first insulation film 170 may be filled with different materials.

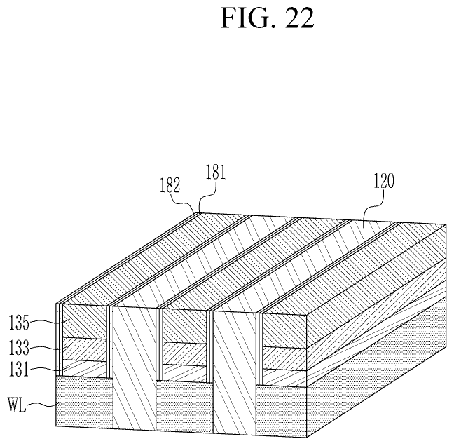

Next, referring to FIG. 22, the first insulation film 170 is removed.

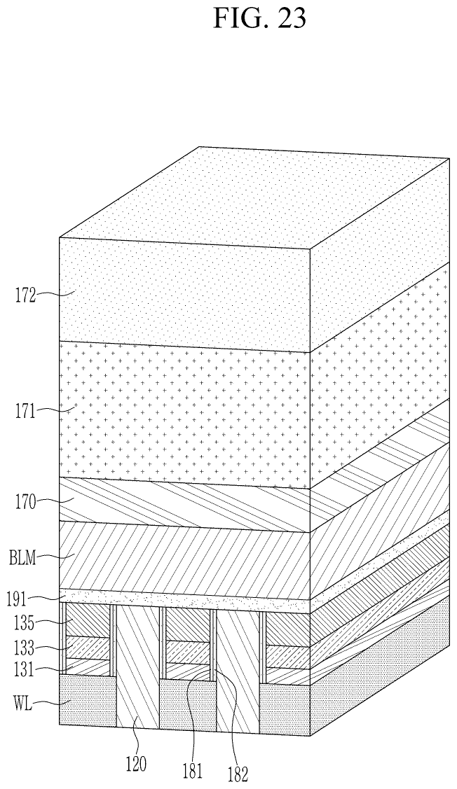

Next, referring to FIG. 23, an interfacial layer 191, a bit line metal layer BLM, the first insulation film 170, the second insulation film 171, and the first patterning film 172 are formed in sequence. The interfacial layer 191 may include TiN, but this is by way of example and is not limited thereto. The descriptions of the materials of the bit line metal layer BLM, the first insulation film 170, the second insulation film 171, and the first patterning film 172 are omitted as they are the same as described above. That is, the bit line metal layer BLM may include tungsten, the first insulation film 170 may include silicon nitride, and the second insulation film 171 may include silicon oxide, but this is by way of example only and embodiments of the present invention are not limited thereto.

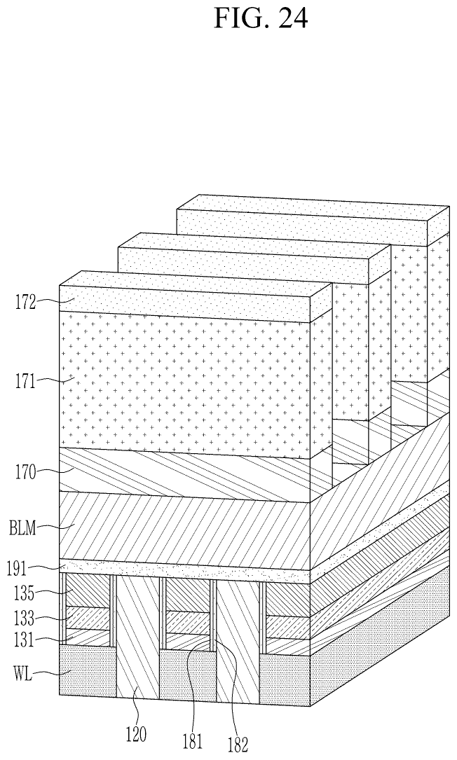

Next, referring to FIG. 24, the first patterning film 172 is patterned and the second insulation film 171 and the first insulation film 170 are etched by using the first patterning film 172 as a mask.

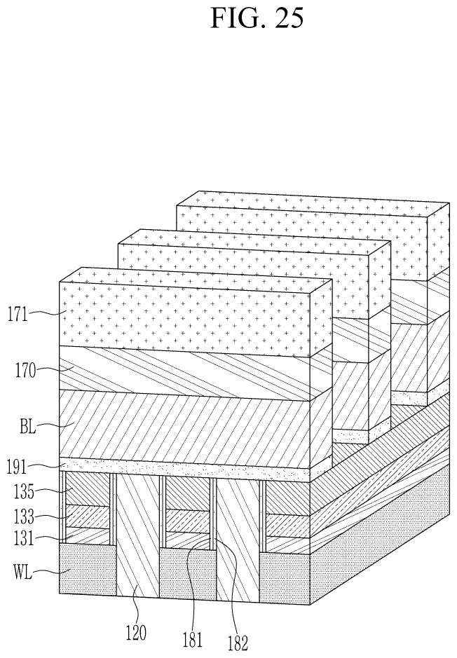

Next, referring to FIG. 25, the first patterning film 172 is removed, and the bit line metal layer BLM and the interfacial layer 191 are etched by using the etched second insulation film 171 and first insulation film 170 to form the bit line BL.

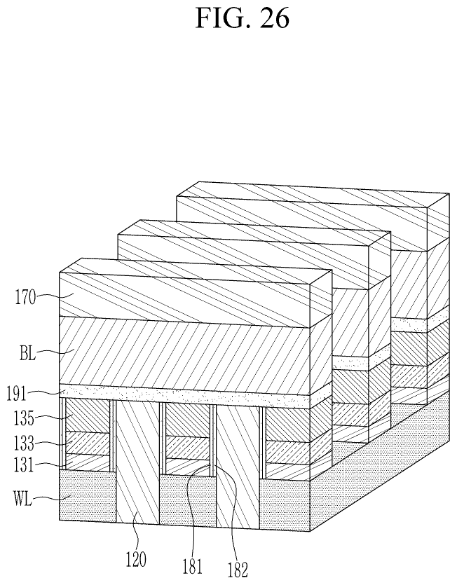

Next, referring to FIG. 26, the first electrode 131, the first OTS film 133, and the second electrode 135 are etched to form a memory cell. In this process, the stack of the first electrode 131, first OTS film 133, and second electrode 135 may be separated from the adjacent stack of the first electrode 131, the first OTS film 133, and the second electrode 135 to form a memory cell. In each memory cell, the first electrode 131 may be in contact with the word line WL and the second electrode 135 may be in contact with the bit line BL.

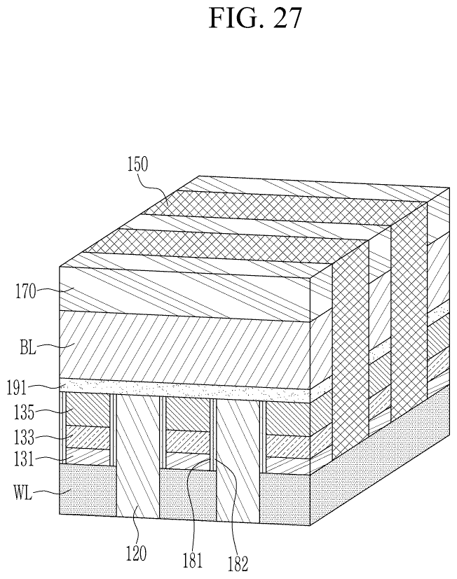

Next, referring to FIG. 27, the space between the etched bit lines BL and the space between the stacks of the first electrode 131, the first OTS film 133, the second electrode 135, and the first insulation film 170 are filled with a second interlayer insulation film 150. The second interlayer insulation film 150 may include, but is not limited to, at least one of silicon oxide, silicon oxynitride, and/or a low dielectric constant (low-k) material having a lower dielectric constant than silicon oxide.

Referring now to FIG. 28, the first insulation film 170 is removed.

In the manufacturing method of FIGS. 16 to 28, the layers configuring the word line metal layer WLM and the memory cell were stacked at one time, and then the memory cell and the word line were formed by stepwise etching. In this case, the etching process of the memory cell and the etching process of the word line are performed at different operations, so that the width of the first electrode 131 of the memory cell and the width of the word line WL may be formed differently.

However, this manufacturing method is only an example, and in other embodiments, the word line may be stacked and formed first and then the memory cell may be stacked and formed.

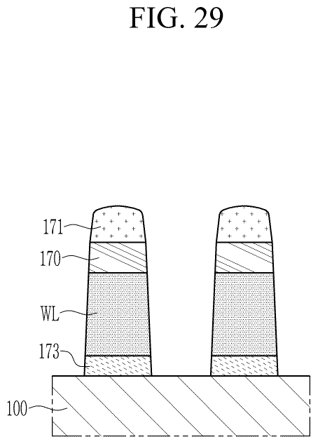

FIGS. 29 to 33 illustrate a method for manufacturing a memory device according to other embodiments. Referring to FIG. 29, a word line WL is first formed on a substrate 100. A first insulation film 170 and a second insulation film 171 may be utilized to form the word line WL. An interfacial layer 173 may be positioned between the word line WL and the substrate 100. For example, the interfacial layer 173 may include, but is not limited to, TiN. In some embodiments, the interfacial layer 173 may be omitted.

In the case of FIG. 29, the interfacial layer 173, the word line metal layer (not illustrated), the first insulation film 170, the second insulation film 171, and the first patterning film (not illustrated) are stacked sequentially, and then the word line WL may be formed by a patterning process. In this process, the width of the word line WL may be formed differently for each region. That is, the width of the word line WL may be formed differently in the first portion, the second portion, and the third portion.

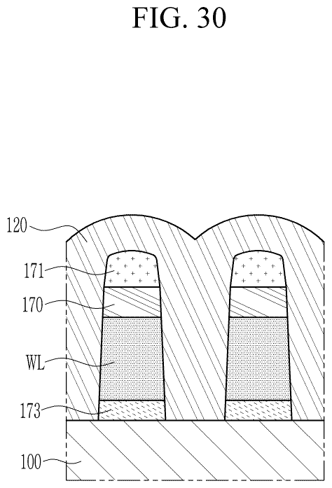

Next, referring to FIG. 30, a first interlayer insulation film 120 is formed between and over the stacks of the word line WL, the first insulation film 170, and the second insulation film 171. In this case, the first interlayer insulation film 120 may include SiN. However, this is an example and embodiments of the present invention are not limited thereto.

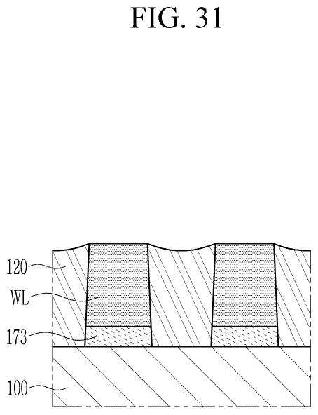

Next, referring to FIG. 31, the first insulation film 170, the second insulation film 171, and the first interlayer insulation film 120 on top of the word line WL may be removed through the CMP process.

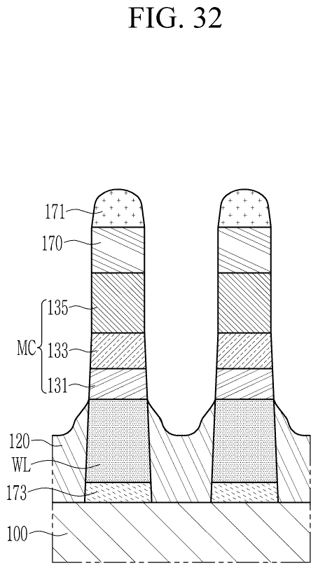

Next referring to FIG. 32, a memory cell MC including the first electrode 131, the first OTS film 133, and the second electrode 135 is then formed on the formed word line WL. Although not illustrated in FIG. 32, the memory cell MC may be formed by a patterning process after forming the first electrode 131, the first OTS film 133 and the second electrode 135, the first insulation film 170 and the second insulation film 171. In present embodiments, the width of the memory cell MC, e.g., the width of the first electrode 131, may be varied.

FIG. 32 illustrates the second portion WAL2 of the memory device, in which the width of the word line WL is the same as the width of the first electrode 131. However, the width of the word line WL may be different for each region. That is, in the first portion WAL1, the width of the word line WL may be formed narrower than the width of the first electrode 131, and in the third portion WAL3, the width of the word line WL may be formed wider than the width of the first electrode 131.

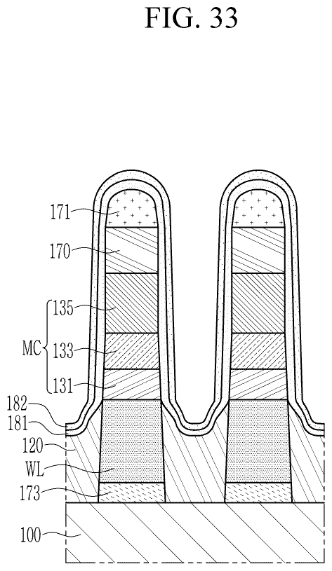

Next, referring to FIG. 33, a first sealing layer 181 and a second sealing layer 182 may be formed on the first electrode 131, the first OTS film 133, the second electrode 135, the first insulation film 170, and the second insulation film 171. In this case, the first sealing layer 181 may include silicon nitride and the second sealing layer 182 may include silicon oxide, but this is an example only and embodiments of the present invention are not limited thereto. The formation process of the first sealing layer 181 and the second sealing layer 182 may be omitted.

As described above, in the manufacturing method according to the embodiments of FIGS. 29 to 33, the word line WL is formed first and then the memory cell MC is formed, so that the width of the word line WL and the width of the first electrode 131 of the memory cell MC may be formed differently for each region.

Although embodiments of the present invention have been described in detail, the scope of the present invention is not limited by these embodiments. Various changes and modifications using the basic concept of the present invention defined in the accompanying claims by those skilled in the art shall be construed to belong to the scope of the present invention.

What is claimed is:

1. A semiconductor memory device comprising:
a substrate;
a plurality of word lines extending along a first direction on the substrate;
a plurality of bit lines on the word lines and extending along a second direction intersecting the first direction; and
a memory cell between the word lines and the bit lines,
wherein a word line of the plurality of word lines comprises a first portion, a second portion, and a third portion, and
wherein, in a plan view, a width of the first portion is less than a width of the second portion in the second direction, and a width of the second portion is less than a width of the third portion in the second direction.

2. The semiconductor memory device of claim 1, wherein the memory cell comprises a first electrode in contact with the word line, a second electrode in contact with a bit line of the plurality of bit lines, and a first OTS film between the first electrode and the second electrode.

3. The semiconductor memory device of claim 2, wherein the width of the first portion of the word line is less than a width of the first electrode in the second direction.

4. The semiconductor memory device of claim 2, wherein the width of the second portion of the word line is equal to a width of the first electrode in the second direction.

5. The semiconductor memory device of claim 2, wherein the width of the third portion of the word line is greater than a width of the first electrode in the second direction.

6. The semiconductor memory device of claim 2, wherein a width of the word line is equal to a width of the first electrode in the second direction, and
wherein a width of the first electrode is less than a width of the first OTS film in the second direction.

7. The semiconductor memory device of claim 2, wherein the first electrode of the memory cell comprises a first portion in contact with the word line and a second portion in contact with the first OTS film, and
wherein a width of the first portion of the first electrode is different from a width of the second portion of the first electrode in the second direction.

8. The semiconductor memory device of claim 7, wherein
the width of the first portion of the first electrode is equal to a width of the word line in contact with the first electrode in the second direction, and
the width of the second portion of the first electrode is equal to a width of the first OTS film in the second direction.

9. The semiconductor memory device of claim 1, wherein the word line is a first word line,
wherein the first portion, the second portion, and the third portion of the first word line extend consecutively in the first direction, and wherein the plurality of word lines further comprises a second word line extending in the first direction, adjacent to the first word line in the second direction, and comprising a third portion, a second portion, and a first portion consecutively in the first direction.

10. The semiconductor memory device of claim 9, wherein the third portion of the first word line is adjacent to the first portion of the second word line in the second direction, and the first portion of the first word line is adjacent to the third portion of the second word line in the second direction.

11. The semiconductor memory device of claim 9, further comprising:
row decoders on opposite ends of the plurality of word lines in the first direction,
wherein the first portion of each word line is directly connected to the row decoder.

12. A semiconductor memory device comprising:
a substrate;
a plurality of word lines extending along a first direction on the substrate;
a plurality of bit lines on the word lines and extending along a second direction intersecting the first direction; and
a memory cell between the word lines and the bit lines and comprising a first electrode in contact with a word line of the plurality of word lines, a second electrode in contact a bit line of the plurality of bit lines, and a first OTS film between the first electrode and the second electrode,
wherein the word line comprises a first portion, a second portion, and a third portion, and
wherein a first area of contact between the first portion of the word line and the memory cell is less than a second area of contact between the second portion of the word line and the memory cell.

13. The semiconductor memory device of claim 12, wherein: at least some of the third portion of the word line does not overlap the memory cell in a third direction perpendicular to the first direction and the second direction.

14. The semiconductor memory device of claim 12, wherein a width of the first portion of the word line is less than a width of the first electrode in the second direction, wherein a width the second portion of the word line is equal to a width of the first electrode in the second direction, and wherein a width of the third portion of the word line is greater than a width of the first electrode in the second direction.

15. The semiconductor memory device of claim 12, wherein a width of the word line is equal to a width of the first electrode, and
wherein a first width of first portion, a second width of the second portion, and a third width of the third portion are different from each other in the second direction.

16. The semiconductor memory device of claim 12, further comprising:
row decoders on opposite ends of the word line in the first direction,
wherein the first portion of the word line is directly connected to one of the row decoders.

17. A semiconductor memory device comprising:
a substrate;
a plurality of word lines extending along a first direction on the substrate and comprising a first word line, a second word line, and other word lines, the second word line and the other word lines adjacent to the first word line in a second direction intersecting the first direction;
a plurality of bit lines on the word lines and extending along the second direction;
a memory cell between the word lines and the bit lines; and
row decoders on opposite ends of the plurality of word lines in the first direction,
wherein a word line of the plurality of word lines comprises a first portion, a second portion, and a third portion consecutively in the first direction,
wherein the first portion, second portion, and third portion have different widths in the second direction,
wherein the second word line comprises a third portion, a second portion, and a first portion consecutively in the first direction, and
wherein the first portion of each word line is directly connected to one of the row decoders.

18. The semiconductor memory device of claim 17, wherein a width of the first portion of the first word line is less than a width of the second portion of the first word line in the second direction, and a width of the second portion of the first word line is less than a width of the third portion of the first word line in the second direction.

19. The semiconductor memory device of claim 17, wherein the memory cell comprises a first electrode in contact with the first word line, a second electrode in contact with a bit line of the plurality of bit lines, and a first OTS film between the first electrode and the second electrode, and
wherein a width of the first portion of the first word line is less than a width of the first electrode.

20. The semiconductor memory device of claim 17, wherein a first area of contact between the first portion of the first word line and the memory cell is less than a second area of contact between the second portion of the first word line and the memory cell.
